(19) United States
(12) Patent Application Publication
(10) Pub. No.: US 2009/0293802 A1
(43) Pub. Date: Dec. 3, 2009

(54) Method of growing silicon single crystals

(76) Inventors: Hiroaki Taguchi, Tokyo (JP); Hideki Hara, Tokyo (JP); Ryoichi Kaito, Tokyo (JP)

Correspondence Address: CLARK & BRODY, 1090 VERMONT AVENUE, NW, SUITE 250, WASHINGTON, DC, 20005, US

(21) Appl. No.: 12/457,065

(22) Filed: Jun. 1, 2009

(30) Foreign Application Priority Data
Jun. 3, 2008 (JP) 2008-145588

(51) Int. Cl. C30B 15/22

(52) U.S. Cl. 117/35; 117/13

(57) ABSTRACT

By giving a shoulder portion height of at least 100 mm in growing silicon single crystals having a diameter of 450 mm (weighing up to 1100 kg) by the CZ method, it becomes possible to inhibit the occurrence of dislocations in the shoulder formation step to thereby achieve a yield improvement and increase productivity. Furthermore, when this method is applied under application of a transverse magnetic field with a predetermined intensity, the occurrence of dislocations can be further inhibited and, accordingly, defect-free silicon single crystals suited for wafer manufacture can be grown with high production efficiency. Thus, the method is best suited for the production of large-diameter silicon single crystals having a diameter of 450 mm, which are applied in the manufacture of semiconductor devices.

### BACKGROUND OF THE INVENTION

1. Field of the Invention

The present invention relates to a method of growing silicon single crystals having a diameter of 450 mm using the Czochralski method (hereinafter referred to as “CZ method”) and, more particularly, to a method of growing silicon single crystals, in which occurrence of dislocations is inhibited in the step of shoulder formation by defining the shape of the shoulder portion.

2. Description of the Related Art

A method of growing silicon single crystals by the CZ method comprises placing a silicon material for semiconductor manufacture in a crucible, heating and melting the silicon material, immersing a seed crystal into the melt and pulling up the seed crystal while rotating the same to thereby causing a silicon single crystal to grow from the bottom of the seed crystal; this method is widely employed for the production of silicon single crystals used for semiconductor substrates.

FIG. 1 is a schematic representation, in vertical cross section, of an essential configuration of a single crystal pulling apparatus suited for growing silicon single crystals by the CZ method. As shown in FIG. 1, this pulling apparatus comprises a heater 1, disposed around a crucible 2 in an approximately concentric manner, for heating the semiconductor silicon material fed into the crucible 2 and maintaining the material in a molten state, and a thermal insulator 3 disposed in the vicinity of the outside surface of the heater.

The crucible 2 has a double structure and is constituted of an inner layer holding vessel 2a made of quartz in the form of a bottomed cylinder (hereinafter referred to as “quartz crucible”) and an outer layer holding vessel 2b made of graphite in the form of a bottomed cylinder and fitted into the outside of the quartz crucible 2a for holding the same (hereinafter referred to as “graphite crucible”), and the crucible 2 is fixed to the upper end of a supporting shaft 4 which is rotatable and movable upward and downward.

A pull wire 6 is disposed above and along the centerline of the crucible 2 containing the melt 5, on the same axis with a supporting shaft 4, and rotates at a predetermined speed either in the reverse direction or the same direction as the supporting shaft, and a seed crystal 7 is held at the lower end of the pull wire.

On the occasion of pulling up a silicon single crystal using the thus-configured pulling apparatus, a predetermined amount of semiconductor silicon raw materials (generally a bulky or granular polycrystalline silicon raw materials) is fed into the crucible 2 and heated and melted by means of the heater 1 disposed around the crucible 2 in an inert gas atmosphere (generally argon (Ar)) at a reduced pressure, and the seed crystal 7 held at the lower end of the pull wire 6 is then immersed into the surface layer of the melt 5 thus formed. Then, while the crucible 2 and pull wire 6 are rotated, the wire 6 is pulled up for growing a single crystal 8 at the lower end face of the seed crystal 7.

On the occasion of pulling up, the diameter of the single crystal 8 formed on the lower end face of the seed crystal 7 is reduced by adjusting the pulling speed and the melt temperature (temperature of the molten silicon) for forming a neck portion (narrowed portion) 9 and, after this necking step, the crystal diameter is allowed to gradually increase to form a cone 10 and further a shoulder portion 11.

Then, a body portion (cylindrical portion) 12 to be used as a source material of product wafers is pulled up. After the length of the body portion 12 reaches a predetermined level, the crystal diameter is caused to gradually decrease to form a tail (not shown), and the tip of the tail is separated from the melt 5; a silicon single crystal 8 having a predetermined shape is thus obtained.

The above-mentioned necking is an essential step for eliminating high-density dislocations introduced into the seed crystal due to heat shock upon contact of the seed crystal with the silicon melt. Through this step, those dislocations are eliminated.

However, in the step of cone and shoulder formation (hereinafter referred to as “shoulder formation step”, including cone formation) following the necking step, dislocations may occur in the crystal in certain instances.

When the diameter of the single crystal once reduced in the necking step is increased in the shoulder formation step, it is a general practice to lower the melt temperature and at the same time reduce the pulling speed. If the melt temperature is lowered abruptly, disturbances tend to be generated at the crystal growth interface, facilitating the occurrence of dislocations. When the change of melt temperature is small, such disturbances occur slightly and dislocations hardly occur; however, the crystal growth becomes slow, and the shoulder portion becomes gradual (the gradient of the shoulder spreading becomes small) in association with the pulling speed and a prolonged period of time is required for the body diameter to reach a predetermined level, so that the length of the body portion relative to the total length of the pulled-up single crystal becomes short. As a result, the productivity of silicon single crystals is reduced.

In the case of growing silicon single crystals having a diameter of 300 mm or smaller, the shoulder formation has so far been made within such a range that will not allow dislocations to occur, based on the experience in practical operations and considering the productivity. The angle of the shoulder (the gradient of the shoulder spreading) relative to the direction of pulling up is generally constant.

On the other hand, in the case of growing silicon single crystals having a larger diameter, for example a diameter of 450 mm, experiences of actual operations are not yet much, so that, referring to the experience in operations in growing silicon single crystals having a diameter of 300 mm or smaller, the height of the shoulder is appropriately adjusted within the range not exceeding 100 mm to avoid the reduction in productivity as resulting from the shortening of the body portion relative to the total length of the pulled-up single crystal. The “height of the shoulder” so referred to herein is the distance, means the distance in the vertical direction between the height level of the site where the shoulder formation begins and the height level of the site where the shoulder formation ends.

Growing such silicon single crystals with a diameter of 450 mm is currently required to produce silicon single crystals as source materials of wafers increased in diameter to follow the recent trends toward intensified integration in semiconductor devices, reduction in cost and improvement in productivity.

However, when the height of the shoulder is less than 100 mm in the case of growing silicon single crystals with a diameter of 450 mm, the frequency of occurrence of dislocations in the shoulder formation step is too high to thereby hinder advancing to the step of growing the body portion, with the result that the yield of pulling up robust single crystals (i.e.,the yield of pulling up single crystals without dislocations; hereinafter referred to as “yield” for short) is lowered and the productivity in silicon single crystal is reduced.

### SUMMARY OF THE INVENTION

The present invention has been made in view of such situations as mentioned above, and an object thereof is to provide a method of shoulder formation ingrowing silicon single crystals having a large diameter of 450 mm by the CZ method according to which method the occurrence of dislocations in the shoulder formation step can be inhibited, the yield can thus be improved and the productivity can be increased accordingly.

To accomplish the above object, the present inventors made investigations in search of a proper range of the shoulder height in pulling up silicon single crystals having a diameter of 450 mm in one of the attempts to specifically define the shape of the single crystal to be pulled up so as to adapt the same to the growth of such crystals.

If dislocations are caused to occur by disturbances at the crystal growth interface, as mentioned above, it will be possible to reduce the gradient/rate of radial broadening of the shoulder (namely, broaden the shoulder gradually) by increasing the height of the shoulder and thus reduce disturbances at the crystal growth interface, rendering it unlikely for dislocations to occur. However, when the shoulder height is excessive, the body portion length becomes short and the silicon single crystal productivity lowers; therefore, it becomes necessary to select a shoulder height suited for maintaining a high productivity level and inhibiting dislocations from occurring.

As a result of investigations, it has been found that when the shoulder height is at least 100 mm, the occurrence of dislocations can be inhibited while good productivity is maintained.

Meanwhile, Japanese Patent Application Publication No. 11-180793 describes a method of controlling the speed of pulling up a single crystal to be grown by the CZ method according to which method the relation L/D≧¼ (wherein L is the length, in a direction of the pull shaft, of the single crystal until it acquires a predetermined body portion diameter by shoulder formation following necking and D is the body portion diameter) should be satisfied in forming the shoulder (shoulder portion) of the single crystal. The above L corresponds to the height of the shoulder so referred to herein in relation to the present invention.

However, an object of the invention described in the above-cited publication No. 11-180793 is to provide a method of controlling the pulling speed to inhibit the formation of ring-like oxidation-induced stacking faults (R-OSF) in the crystal plane to be utilized in manufacturing wafers, and the single crystals produced in the examples have a diameter of 8 inches (203 mm); thus, the object of the above invention differs from that of the present invention and, in addition, the target single crystals greatly differ in diameter from those of the present invention.

Further, while the application of a transverse magnetic field on the occasion of growing silicon single crystals is in wide use since the application of a transverse magnetic field reduces temperature changes in the vicinity of the crystal growth interface and, as a result, the concentration distribution of a dopant and other impurities can be homogenized and, further, provides other advantages that, for example, the rate of crystal growth can be increased, it has been confirmed that the effects of selecting a shoulder height of at least 100 mm in growing silicon single crystals having a diameter of 450 mm are also produced under application of a transverse magnetic field.

The gist of the present invention consists in “a method of growing silicon single crystals having a diameter of 450 mm by the CZ method which comprises growing such silicon single crystals after forming the shoulder portion having a height, from the neck portion to the body portion, of at least 100 mm.”

The phrase “silicon single crystals having a diameter of 450 mm” as used herein means the silicon single crystals to be used as source materials for manufacturing product wafers; hence, the single crystals as pulled up may have a diameter of 460-470 mm.

The phrase “height from the neck portion to the body portion” refers to the height of the shoulder portion (herein including the cone) successively formed from the neck portion side toward the body portion. Thus, it is the distance, in a vertical direction, between the height level of the position at which the shoulder formation begins and the height level of the position at which the shoulder formation ends; it is the shoulder height represented by the symbol h in FIG. 2 to be referred to later herein.

The above-mentioned shoulder formation method according to the present invention can also be carried out in a mode of embodiment in which the silicon single crystal grow this effected under application of a transverse magnetic field having an intensity of not lower than 0.1 T.

According to the growing method of the present invention, a silicon single crystal having a diameter of 450 mm can be grown by the CZ method while inhibiting the occurrence of dislocations in the shoulder formation step; thus, the yield can be improved and the productivity can be increased.

Further, it is desirable to carry out the growing method of the present invention in a manner such that a transverse magnetic field having a predetermined intensity is applied in growing silicon single crystals; under such conditions, the effect of inhibiting the introduction of point defects is produced in addition to the effect of inhibiting the occurrence of dislocations in the shoulder formation step and the yield is thus improved and, in addition, a high level of production efficiency can be attained owing to the increase in the rate of crystal growth.

### BRIEF DESCRIPTION OF THE DRAWINGS

FIG. 1 is a schematic representation, in vertical cross section, of an essential configuration of a single crystal pulling apparatus suited for growing silicon single crystals by the CZ method.

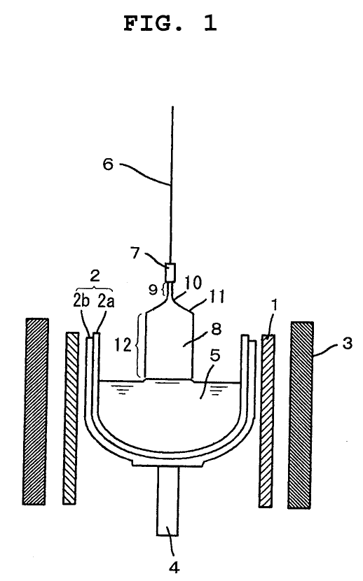

FIG. 2 is a figure for illustrating the shoulder formation method to be employed in the practice of the present invention, and is a schematic representation of a silicon single crystal having a diameter of 450 mm at a certain time point in the course of pulling up the same as shown in vertical cross section with the central axis C therein.

### DETAILED DESCRIPTION OF THE PREFERRED EMBODIMENTS

The method of growing a silicon single crystal according to the present invention comprises forming the shoulder having a height of at least 100 mm from the neck portion to the body portion in growing a silicon single crystal having a diameter of 450 mm by the CZ method.

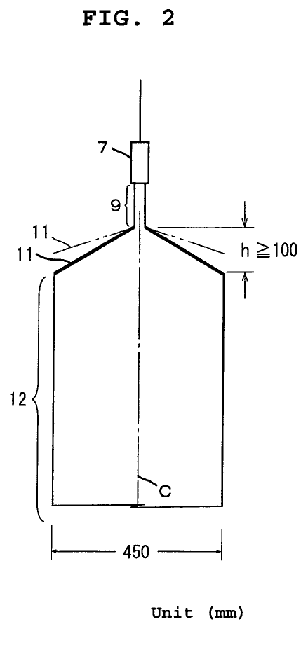

FIG. 2 is for illustrating the shoulder formation method to be employed in the practice of the present invention, and is a schematic representation of a silicon single crystal having a diameter of 450 mm at a certain time point in the course of pulling up the same as shown in vertical cross section with the central axis C therein. As shown in FIG. 2, a neck portion 9 is formed on the lower end face of a seed crystal 7 by reducing the diameter and then a shoulder portion 11 (portion indicated by bold solid lines in the figure) is formed from the neck portion 9 to a body portion 12. On that occasion, the height from the neck portion to the body portion (height of the shoulder) h is set to at least 100 mm.

In accordance with the growing method of the present invention, the diameter of silicon single crystals to be grown is specified to be 450 mm since it is intended to provide silicon single crystals to serve as source materials for large-diameter wafers which are much sought after in view of recent trends toward intensified integration in semiconductor devices, reductions in cost and improvements in productivity.

The shoulder height h in the shoulder formation employed by the present invention should be at least 100 mm so that the occurrence of dislocations in the shoulder formation step may be inhibited, the yield may be improved and the productivity may be increased in growing silicon single crystals having a diameter of 450 mm.

According to the prior art, single crystal growing is carried out while appropriately adjusting the shoulder height within the range not exceeding 100 mm, for example as indicated by long dashed double-dotted line in FIG. 2, taking into an account possible reduction in productivity due to the decrease in body portion length. In that case, the shoulder height h is relatively small, so that the broadening gradient of the shoulder 11 on the occasion of proceeding to the formation of the shoulder 11 following the necking step becomes large, and hence it becomes necessary to lower the melt temperature rapidly.

As a result, considerable disturbances are caused at the crystal growth interface, readily leading to the occurrence of dislocations. On the contrary, when the shoulder height h is selected at a level of 100 mm or more, as indicated by bold solid lines in FIG. 2, the radial spreading gradient, in the direction of diameter, of the shoulder portion 11 can be made small (gradual) and the abrupt lowering of the melt temperature can be moderated, and hence it becomes possible to reduce disturbances at the crystal growth interface and thus circumvent the occurrence of dislocations.

An upper limit of the shoulder height h is not particularly specified herein, but, from the viewpoint of securing desired yield levels, the upper limit is desirably set at 350 mm to 400 mm.

In carrying out the shoulder formation method employed in the practice of the present invention, the melt temperature is lowered following the completion of the necking step and at the same time the pulling speed is reduced to increase in diameter for the single crystal so that the shoulder height h may reach a level of at least 100 mm. Although it is more advantageous, for improving the yield and increasing the productivity, to reduce the shoulder height, it is desirable, from the viewpoint of inhibiting the occurrence of dislocations so as to obtain robust crystals, to increase the shoulder height h to render the shoulder gradient gentle/gradual.

In carrying out the above-mentioned growing method of the present invention, a mode of embodiment such that the silicon single crystal growth is effected under application of a transverse magnetic field with an intensity of not less than 0.1 T is desirably employed.

The application of such a transverse magnetic field on the occasion of growing silicon single crystals inhibits the convection of the melt in the crucible and markedly reduces temperature changes in the vicinity of the crystal growth interface, so that the concentration distribution of a dopant, such as phosphorus to be incorporated into the crystal, and of other impurities is homogenized. Further, the introduction of point defects into the crystal is inhibited, so that crystals suited for wafer manufacture can be obtained in good yield; furthermore, the rate of crystal growth can be increased.

The intensity of the transverse magnetic field should be not less than 0.1 T since, at levels below 0.1 T, the convection of the melt is retarded only to an insufficient extent, and hence the effect of transverse magnetic field application is not produced to a satisfactory extent. The upper limit thereof is not particularly specified herein but is desirably set at 0.7 T or less since when an excessively intense transverse magnetic field is employed, the equipment for magnetic field application becomes large in size and the electric power consumption increases.

When the growing method of the present invention is carried out under application of a transverse magnetic field in a manner mentioned above, point defect-free silicon single crystals can be grown with high production efficiency in addition to the effect of inhibiting the occurrence of dislocations in the above-mentioned shoulder formation step to thereby provide a yield improvement.

By carrying out the above-mentioned growing method of the present invention, it becomes possible to inhibit the occurrence of dislocations and thereby achieve a yield improvement and accordingly contribute to improve the productivity. In particular, when the shoulder formation method of the present invention is applied under application of a transverse magnetic field with a predetermined intensity, the effect of transverse magnetic field application can also be exerted.

### EXAMPLES

Investigations were made by numerical simulation in search of a proper shoulder height range to be employed in the shoulder formation step in growing large-diameter silicon single crystals having a diameter of 450 mm.

Silicon single crystals each having a diameter of 450 mm and a body portion length of 1800 mm or 2500 mm and having a gross weight of about 800 kg or about 1100 kg, respectively, were grown. The quartz crucible to be used was a 36-inch in nominal size(opening diameter 914 mm, crucible height 600 mm) or a 44-inch in nominal size (opening diameter 1118 mm, crucible height 625 mm) according to the body portion length mentioned above. When the 36-inch quartz crucible is filled with a melt to the height of 590 mm or the 44-inch quartz crucible to the height of 563 mm, the weight of silicon raw materials comes to be about 800 kg or about 1100 kg, respectively.

Analysis results of the numerical simulation for the various shoulder portion heights, namely 60 mm, 80 mm, 100 mm, 200 mm and 300 mm, turned out that dislocations occur when the shoulder portion height is less than 100 mm, while the occurrence of dislocations is not found when the shoulder portion height is 100 mm or more. These results make it possible to assume that when the shoulder portion height in growing large-diameter silicon single crystals having a diameter of 450 mm is less than 100 mm, dislocations will occur.

As explained hereinabove, the method of growing silicon single crystals according to the present invention, which comprises forming the shoulder portion having a shoulder height of at least 100 mm in growing silicon single crystals having a diameter of 450 mm by the CZ method, makes it possible to inhibit the occurrence of dislocations in the shoulder formation step, achieve a yield improvement and increase productivity.

When the growing method of the present invention is applied under application of a transverse magnetic field having a predetermined intensity, the occurrence of dislocations in the shoulder formation step can be inhibited and defect-free silicon single crystals suited for wafer manufacture can be grown with high production efficiency.

Accordingly, the shoulder formation method employed according to the present invention can be effectively employed in the production of large-diameter silicon single crystals having a diameter of 450 mm which are suited for use in the field of semiconductor device manufacture.

1. A method of growing silicon single crystals having a diameter of 450 mm by the Czochralski method, comprising forming a shoulder in each silicon single crystal so that the height thereof from a neck portion to a body portion be not less than 100 mm.

2. The method of growing silicon single crystals according to claim 1, wherein growing of the silicon single crystal is carried out under application of a transverse magnetic field having an intensity of not less than 0.1 T.

3. The method of growing silicon single crystals according to claim 1, wherein the height from the neck portion to the body portion is 350 mm to 400 mm.

4. The method of growing silicon single crystals according to claim 3, wherein growing of the silicon single crystal is carried out under application of a transverse magnetic field having an intensity of not less than 0.1 T.

5. The method of growing silicon single crystals according to claim 1, wherein the silicon single crystal after being pulled up has a gross weight of 800 kg to 1100 kg.

6. The method of growing silicon single crystals according to claim 2, wherein the silicon single crystal after being pulled up has a gross weight of 800 kg to 1100 kg.

7. The method of growing silicon single crystals according to claim 3, wherein the silicon single crystal after being pulled up has a gross weight of 800 kg to 1100 kg.

8. The method of growing silicon single crystals according to claim 4, wherein the silicon single crystal after being pulled up has a gross weight of 800 kg to 1100 kg.
